(19) United States
(12) Patent Application Publication
(10) Pub. No.: US 2018/0019733 A1
(43) Pub. Date: Jan. 18, 2018

(54) MULTI-LEVEL CLOCK GATE CONTROLS TO ADDRESS SCAN MODE POWER DROOP AND VOLTAGE BUMP REQUIREMENT

(71) Applicant: QUALCOMM Incorporated, San Diego, CA (US)

(72) Inventors: Rajesh Tiwari, Bangalore (IN); Venkata Raghava Sesha Sai Aduru, Bangalore (IN); Nishi Bhushan Singh, Bangalore (IN)

(21) Appl. No.: 15/210,724

(22) Filed: Jul. 14, 2016

(51) Int. Cl. H03K 3/037; H04L 12/26; H04L 5/00; H04W 88/08; H04W 88/02

(52) U.S. Cl. CPC H03K 3/037; H04L 43/50; H04L 43/08; H04L 5/0021; H04W 88/02; H04W 88/08

(57) ABSTRACT

Embodiments described herein provide a method and apparatus for multi-level clock gate control for testing electronic devices. The method begins when the number of clock gate controls from root level to the last leaf level are identified and then ranked from the root to last leaf level. A number of test enable commands for testing at least one block of an electronic device are determined. These commands selectively connect and disconnect the test enable commands based on the ranked clock gate levels. The apparatus includes a chain of at least two uncompressed flip-flops with additional flip-flops added to provide multi-level clock gate control during testing. An OR gate in communication with each added flip-flop provides the logic functions to selectively connect and disconnect the test enable command A decompressor and a compressor is in communication with the chain of at flip-flops and the OR gates.

### FIELD

The present disclosure relates generally to wireless communication systems, and more particularly to a method and apparatus that provide multi-level clock gate controls to address scan mode power droop and voltage bump requirements.

### BACKGROUND

Wireless communication devices have become smaller and more powerful as well as more capable. Increasingly users rely on wireless communication devices for mobile phone use as well as email and Internet access. At the same time, devices have become smaller in size. Devices such as cellular telephones, personal digital assistants (PDAs), laptop computers, and other similar devices provide reliable service with expanded coverage areas. Such devices may be referred to as mobile stations, stations, access terminals, user terminals, subscriber units, user equipment, and similar terms.

A wireless communication system may support communication for multiple wireless communication devices at the same time. In use, a wireless communication device may communicate with one or more base stations by transmissions on the uplink and downlink. Base stations may be referred to as access points, Node Bs, or other similar terms. The uplink or reverse link refers to the communication link from the wireless communication device to the base station, while the downlink or forward link refers to the communication from the base station to the wireless communication devices.

Wireless communication systems may be multiple access systems capable of supporting communication with multiple users by sharing the available system resources, such as bandwidth and transmit power. Examples of such multiple access systems include code division multiple access (CDMA) systems, time division multiple access (TDMA) systems, frequency division multiple access (FDMA) systems, wideband code division multiple access (WCDMA) systems, global system for mobile (GSM) communication systems, enhanced data rates for GSM evolution (EDGE) systems, and orthogonal frequency division multiple access (OFDMA) systems.

Power consumption during scan mode of circuit operation is an area of concern for high performance circuits. Mobile system modems (MSM), which may be used in many devices, may be designed to operate at more than 3 GHz. This demanding performance requirement may require extensive testing. During this testing a scan mode is used to capture information about how the MSM is behaving during testing. Logic activity during scan capture of test pattern data may be sufficient to support only the functional power budget and may not be able to sustain the higher power demands of scan capture, which may lead to excessive scan capture power and voltage droop. As a result, at-speed testing becomes challenging, or may be performed at an elevated power level, Vbump. Structural testing run with normal power and Vbump power may mask real timing defects and lead to a higher defect rate per million parts.

There is a need in the art for a method and apparatus for multi-level clock gate controls to address scan mode power droop and voltage bump requirements.

### SUMMARY

Embodiments described herein provide a method for multi-level clock gate control for testing electronic devices. The method begins when the number of clock gate controls from root level to the last leaf level are identified. These levels are then ranked from the root level to the last leaf level. Next, a number of test enable commands for testing at least one block of an electronic device are determined. During testing, these commands are used to selectively connect and disconnect the test enable commands based on the ranked clock gate levels. This method may be repeated for each block of an electronic device.

A further embodiment provides an apparatus for multi-level clock gate control for testing electronic devices. The apparatus includes a chain of at least two uncompressed flip-flops. Additional flip-flops may be added to the uncompressed flip-flop chain to provide multi-level clock gate control during testing of an electronic device. The flip-flops added to provide multi-level gate control are each in communication with an OR gate to provide the logic functions to selectively connect and disconnect the test enable command during testing. A decompressor is in communication with the chain of at least two uncompressed flip-flops and an at least one flip-flop in communication with an OR gate. A compressor is also in communication with the chain of at least two uncompressed flip-flops and the at least one flip-flop in communication with an OR gate.

A still further embodiment provides an apparatus for multi-level clock gate control for testing electronic devices. The apparatus includes: means for identifying a number of clock gate levels from root level to least leaf level; means for ranking the clock gate levels from the root level to the last leaf level; means for determining a number of test enable commands for at least one test block of an electronic device; means for selectively connecting and disconnecting the test enable commands based on the ranked clock gate levels; and means for testing the at least one electronic device.

A yet further embodiment provides a non-transitory computer-readable medium containing instructions, which when executed, cause a processor to perform the following steps: identify a number of clock gate levels from root level to last leaf level; rank the clock gate levels from the root level to the last leaf level; determine a number of test enable commands for at least one test block of an electronic device; selectively connect and disconnect the test enable commands based on the ranked clock gate levels; and test that at least one test block of the electronic device.

### BRIEF DESCRIPTION OF THE DRAWINGS

FIG. 1 illustrates a wireless multiple-access communication system, in accordance with certain embodiments of the disclosure.

FIG. 2 is a block diagram of a wireless communication system in accordance with embodiments of the disclosure.

FIG. 3 is a block diagram of a system-on-chip (SoC), in accordance with certain embodiments of the disclosure.

FIG. 4 depicts the current clock tree and architecture, in accordance with certain embodiments of the disclosure.

FIG. 5 illustrates fine grain control of a multi-level clock gate control architecture, in accordance with certain embodiments of the disclosure.

FIG. 6 shows coarse gain control of a multi-level clock gate control architecture, in accordance with certain embodiments of the disclosure.

FIG. 7 depicts a block diagram of a circuit to control the test enable function of a multi-level clock gate control architecture, in accordance with certain embodiments of the disclosure.

FIG. 8 depicts the change to the architecture that allows control of the test enable function in a multi-level clock gate control architecture, in accordance with certain embodiments of the disclosure.

FIG. 9 is a flowchart of a method that provides multi-level clock gate control to address scan mode power droop and voltage bump requirements, in accordance with certain embodiments of the disclosure.

### DETAILED DESCRIPTION

The detailed description set forth below in connection with the appended drawings is intended as a description of exemplary embodiments of the present disclosure and is not intended to represent the only embodiments in which the present disclosure can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the present disclosure. It will be apparent to those skilled in the art that the exemplary embodiments of the present disclosure may be practiced without these specific details. In some instances, well-known structures and devices are shown in block diagram form in order to avoid obscuring the novelty of the exemplary embodiments presented herein.

As used in this application, the terms “component,” “module,” “system,” and the like are intended to refer to a computer-related entity, either hardware, firmware, a combination of hardware and software, software, or software in execution. For example, a component may be, but is not limited to being, a process running on a processor, an integrated circuit, a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets (e.g., data from one component interacting with another component in a local system, distributed system, and/or across a network, such as the Internet, with other systems by way of the signal).

Furthermore, various aspects are described herein in connection with an access terminal and/or an access point. An access terminal may refer to a device providing voice and/or data connectivity to a user. An access wireless terminal may be connected to a computing device such as a laptop computer or desktop computer, or it may be a self-contained device such as a cellular telephone. An access terminal can also be called a system, a subscriber unit, a subscriber station, mobile station, mobile, remote station, remote terminal, a wireless access point, wireless terminal, user terminal, user agent, user device, or user equipment. A wireless terminal may be a subscriber station, wireless device, cellular telephone, PCS telephone, cordless telephone, a Session Initiation Protocol (SIP) phone, a wireless local loop (WLL) station, a personal digital assistant (PDA), a handheld device having wireless connection capability, or other processing device connected to a wireless modem. An access point, otherwise referred to as a base station or base station controller (BSC), may refer to a device in an access network that communicates over the air-interface, through one or more sectors, with wireless terminals. The access point may act as a router between the wireless terminal and the rest of the access network, which may include an Internet Protocol (IP) network, by converting received air-interface frames to IP packets. The access point also coordinates management of attributes for the air interface.

Moreover, various aspects or features described herein may be implemented as a method, apparatus, or article of manufacture using standard programming and/or engineering techniques. The term “article of manufacture” as used herein is intended to encompass a computer program accessible from any computer-readable device, carrier, or media. For example, computer readable media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick, key drive . . . ), and integrated circuits such as read-only memories, programmable read-only memories, and electrically erasable programmable read-only memories.

Various aspects will be presented in terms of systems that may include a number of devices, components, modules, and the like. It is to be understood and appreciated that the various systems may include additional devices, components, modules, etc. and/or may not include all of the devices, components, modules etc. discussed in connection with the figures. A combination of these approaches may also be used.

Other aspects, as well as features and advantages of various aspects, of the present disclosure will become apparent to those of skill in the art through consideration of the ensuring description, the accompanying drawings and the appended claims.

Embodiments described herein relate to an architecture for multi-level clock gate controls that address scan mode power droop and voltage bump requirements. This architecture may be used as part of a testing process for a system-on-chip (SoC) device. Testing a SoC may be complex and time consuming. During testing power consumption during the scan mode may be a major concern for high performance circuits. Many mobile system modems (MSMs) may be designed for more than 3 GHz operation. During testing of these devices the logic activity during the capture of test pattern data may lead to excessive power consumption and voltage droop.

Excessive power consumption and voltage droop may arise because the power grid may be designed to support only the functional power budget and not to sustain a high power budget that may occur during scan capture. Under such circumstances, the power grid may not be able to sustain the increased scan capture power. When this occurs, at-speed testing may become challenging or may be performed at an elevated voltage (Vnormal+Vbump). Running structural tests of the SoC with the additional voltage may mask real-time timing defects, and may lead to a higher defect rate per parts per million.

Embodiments described below utilize customizable test systems and clock gate levels to address scan mode power droop and voltage bump requirements. The approach begins with identifying the number of clock gate levels from the root level to the leaf level. These clock gate levels are then ranked from the root, which is ranked at 0, to the last leaf, which is ranked as N. Once this ranking has been completed, the number of test enable (t_en) commands that may be required for the given block to be tested may be determined. The number of t_en commands may be based on the maximum number of flip-flops in a clock domain. These test enable commands may be shared across the clock domains. Test control procedures, which may vary depending on the test tool being used, are used to trace the clock gates for connecting and disconnecting the test enable controls.

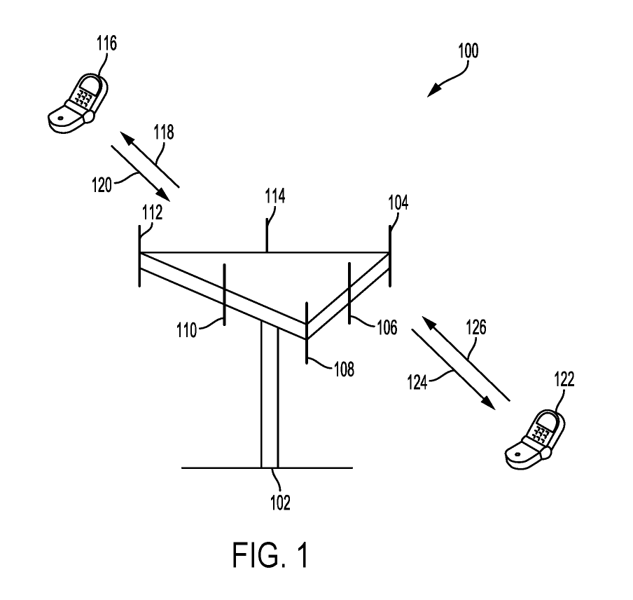

FIG. 1 illustrates a multiple access wireless communication system 100 according to one aspect. An access point 102 (AP) includes multiple antenna groups, one including 104 and 106, another including 108 and 110, and an additional one including 112 and 114. In FIG. 1, only two antennas are shown for each antenna group, however, more or fewer antennas may be utilized for each antenna group. Access terminal 116 (AT) is in communication with antennas 112 and 114, where antennas 112 and 114 transmit information to access terminal 116 over downlink or forward link 118 and receive information from access terminal 116 over uplink or reverse link 120. Access terminal 122 is in communication with antennas 106 and 108, where antennas 106 and 108 transmit information to access terminal 122 over downlink or forward link 124, and receive information from access terminal 122 over uplink or reverse link 126. In a frequency division duplex (FDD) system, communication link 118, 120, 124, and 126 may use a different frequency for communication. For example, downlink or forward link 118 may use a different frequency than that used by uplink or reverse link 120.

Each group of antennas and/or the area in which they are designed to communicate is often referred to as a sector of the access point. In an aspect, antenna groups are each designed to communicate to access terminals in a sector of the areas covered by access point 102.

In communication over downlinks or forward links 118 and 124, the transmitting antennas of an access point utilize beamforming in order to improve the signal-to-noise ratio (SNR) of downlinks or forward links for the different access terminals 116 and 122. Also, an access point using beamforming to transmit to access terminals scattered randomly through its coverage causes less interference to access terminals in neighboring cells than an access point transmitting through a single antenna to all its access terminals.

An access point may be a fixed station used for communicating with the terminals and may also be referred to as a Node B, an evolved Node B (eNB), or some other terminology. An access terminal may also be called a mobile station, user equipment (UE), a wireless communication device, terminal or some other terminology. For certain aspects, either the AP 102, or the access terminals 116, 122 may utilize the techniques described below to improve performance of the system.

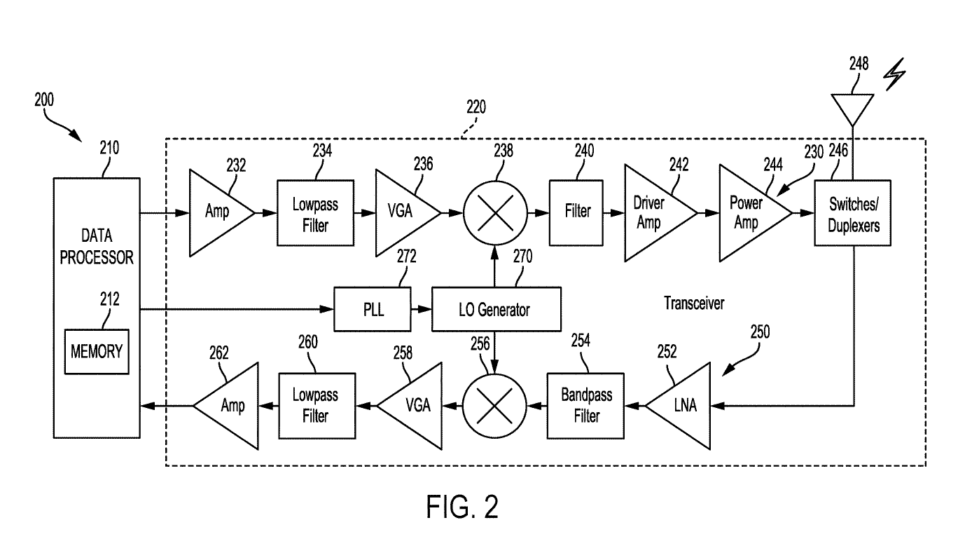

FIG. 2 shows a block diagram of an exemplary design of a wireless communication device 200. In this exemplary design, wireless device 200 includes a data processor 210 and a transceiver 220. Transceiver 220 includes a transmitter 230 and a receiver 250 that support bi-directional wireless communication. In general, wireless device 200 may include any number of transmitters and any number of receivers for any number of communication systems and any number of frequency bands.

In the transmit path, data processor 210 processes data to be transmitted and provides an analog output signal to transmitter 230. Within transmitter 230, the analog output signal is amplified by an amplifier (Amp) 232, filtered by a low pass filter 234 to remove images caused by digital-to-analog conversion, amplified by a variable gain amplifier (VGA) 236, and upconverted from baseband to RF by a mixer 238. The upconverted signal is filtered by a filter 240, further amplified by a driver amplifier, 242 and a power amplifier 244, routed through switches/duplexers 246, and transmitted via an antenna 248.

In the receive path, antenna 248 receives signals from base stations and/or other transmitter stations and provides a received signal, which is routed through switches/duplexers 246 and provided to receiver 250. Within receiver 250, the received signal is amplified by an LNA 252, filtered by a bandpass filter 254, and downconverted from RF to baseband by a mixer 256. The downconverted signal is amplified by a VGA 258, filtered by a low pass filter 260, and amplified by an amplifier 262 to obtain an analog input signal, which is provided to data processor 210.

FIG. 2 shows transmitter 230 and receiver 250 implementing a direct-conversion architecture, which frequency converts a signal between RF and baseband in one stage. Transmitter 230 and/or receiver 250 may also implement a super-heterodyne architecture, which frequency converts a signal between RF and baseband in multiple stages. A local oscillator (LO) generator 270 generates and provides transmit and receive LO signals to mixers 238 and 256, respectively. A phase locked loop (PLL) 272 receives control information from data processor 210 and provides control signals to LO generator 270 to generate the transmit and receive LO signals at the proper frequencies.

FIG. 2 shows an exemplary transceiver design. In general, the conditioning of the signals in transmitter 230 and receiver 250 may be performed by one or more stages of amplifier, filter, mixer, etc. These circuits may be arranged differently from the configuration shown in FIG. 2. Some circuits in FIG. 2 may also be omitted. All or a portion of transceiver 220 may be implemented on one or more analog integrated circuits (ICs), RF ICs (RFICs), mixed-signal ICs, etc. For example, amplifier 232 through power amplifier 244 in transmitter 230 may also be implemented on an RFIC. Driver amplifier 242 and power amplifier 244 may also be implemented on another IC external to the RFIC.

Data processor 210 may perform various functions for wireless device 200, e.g., processing for transmitter and received data. Memory 212 may store program codes and data for data processor 210. Data processor 210 may be implemented on one or more application specific integrated circuits (ASICs) and/or other ICs.

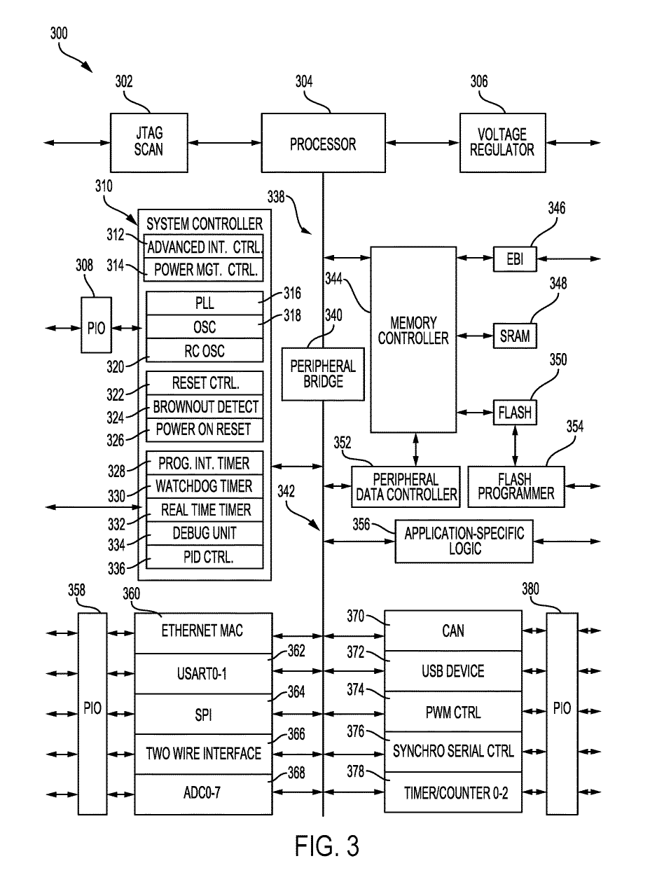

FIG. 3 illustrates a SoC 300. The assembly 300 includes joint test action group (JTAG) scan device 302, which receives input signals for scanning. These signals are scanned before being sent to the ARM processor 304. The ARM processor 304 may also send input to JTAG scan device 302, which in turn may provide output. The ARM processor 304 also interfaces with voltage regulator 306. The SoC 300 may also incorporate a first peripheral input/output interface (PIO) 308. This PIO 308 interfaces with a system controller 310. System controller 310 may incorporate an advanced interface controller 312, a power management controller 314, a phase locked loop (PLL) 316, an oscillator 318, a resistor-capacitor (RC) oscillator 320, a reset controller 322, a brownout detector 324, a power on reset device 326, a program interrupt timer 328, a watchdog timer 330, a real time timer 332, a debug unit 334, and proportional/integral/derivative (PID) controller 336. All of the devices are under the control of the system controller 310 interface through the PIO.

The ARM processor 304 interfaces with the peripheral bridge 340 which also provides input and output interface with the system controller 310. The peripheral bridge communicates with multiple components using an application peripheral bus (APB) 342. An internal bus 338 operates in conjunction with the peripheral bridge 340 to communicate with additional devices within the SoC 300. The internal bus 338 may be an application specific bus (APB) or an application handling bus (AHB). Memory controller 340 interfaces with ARM processor 304 using internal bus 338. The memory controller 340 also communicates with the external bus interface (EBI) 346. Memory controller 340 is also in communication with static random access memory (SRAM) 348, and with flash memory 350. Flash memory 350 is in communication with flash programmer 354. The memory controller 344 is also in communication with peripheral data controller 352. Additional application specific logic 356 communicates with the internal bus 338 and may also have external connections. A second PIO 358 provides communication with an Ethernet medium access control (MAC) 360. The second PIO 358 also communicates with a universal asynchronous receiver/transmitter 362, a serial peripheral interface (SPI) 364, a two wire interface 366, and an analog to digital converter 368. These devices and interfaces connect through internal bus 338 with a controller area network bus (CAN) 370, universal serial bus (USB) devices 372, a pulse width modulator (PWM) controller 374, a synchro serial controller 376, and a timer/counter 378. These devices CAN 370, USB device 372, PWM controller 374, synchro serial controller 376, and timer/counter 378 interface with third PIO 380, which provides external input and output. While these elements are typical of many SoCs, other devices may be incorporated, and some may not be included.

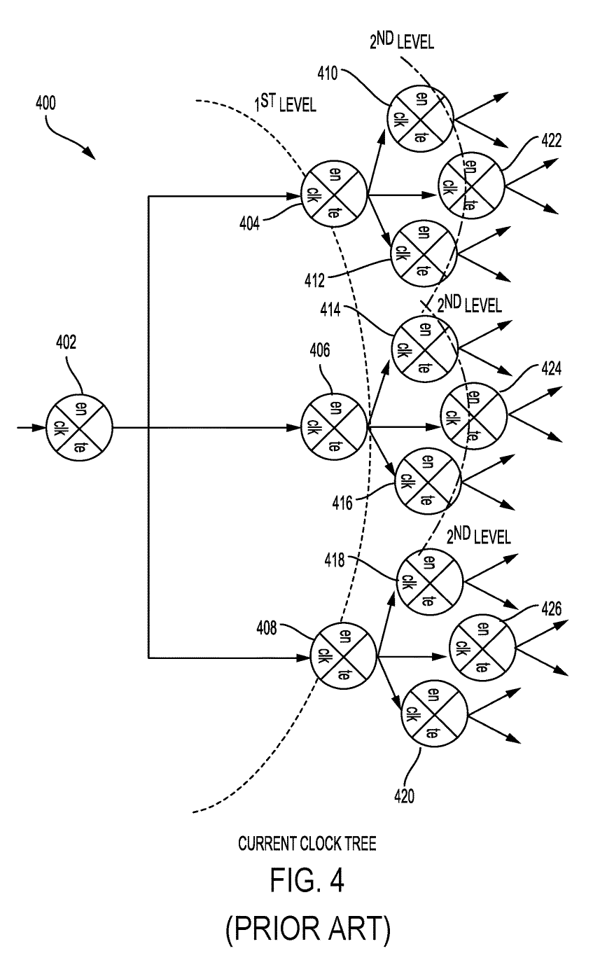

FIG. 4 shows prior art logic test architecture with a single test enable command control used for the full design test. The architecture 400 includes the multi-level clock gate select 402. Multi-level clock gate select logic block 402 provides for selection between clock input (clk), a functional enable command (en), and a test enable command (te). The multi-level clock gate select logic block 402 provides input to further multi-level clock gate select logic blocks in a first level of testing. Additional multi-level clock gate select logic blocks 404, 406, and 408 comprise the first level of test enable selection. In turn, each of blocks 404, 406, and 408 provide input to multi-level clock gate select logic blocks in the second level. The second level multi-level clock gate select logic blocks are 410, 412, 414, 416, 418, and 420. These second level multi-level clock gate select logic blocks in turn may provide input to additional multi-level clock gate logic select blocks 422, 424, and 426. If the test enable command (test_en) is set to 1, a logic high state, then all clock gates (clk) are tuned on and are active during testing. In this situation, the power budget for the device under test (DUT) may be violated.

If the test enable command (test_en) is set to 0, a logic low state, then testing relies on the functional enable (en). When the functional enable command is used, the tool run time may become very high. In addition, there may be coverage loss and a greater increase in patterns that must be tested. Attempting to solve these problems using the automatic test pattern generation functions included in many test tools does not resolve the problems as the effort required to implement such an option may be high. Moreover, run times may increase dramatically and the amount of coverage provided is less. While this option does honor the power budget is some cases, and does not result in a voltage bump, the run time and coverage problems do not compensate. In other cases, the power budget may not be honored and the problems mentioned above arise as well.

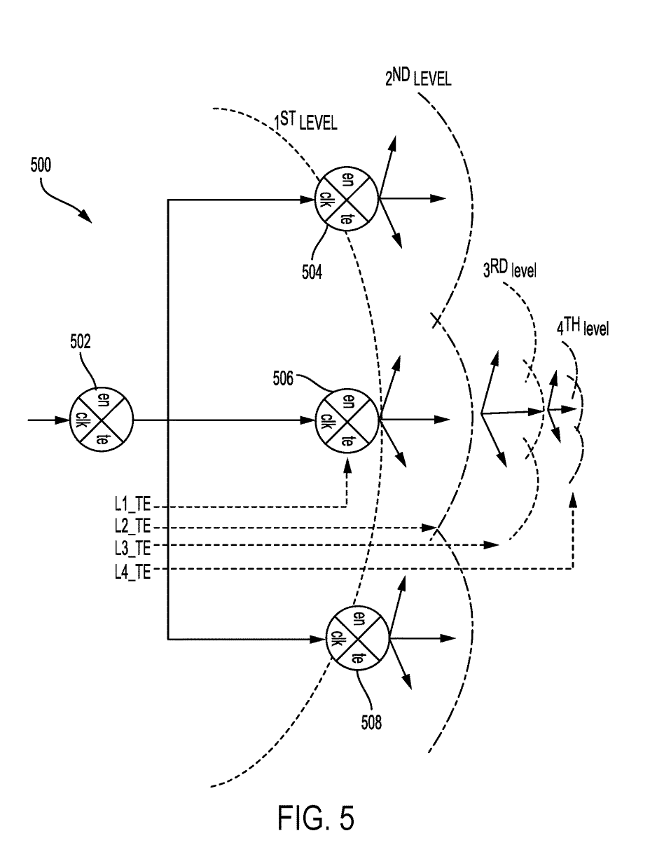

FIG. 5 illustrates a logic architecture that provides fine grain control. In this embodiment that architecture is based on the level of the clock gates in the clock tree and provides multiple test enable controls to turn on clock gates during testing. The architecture is adaptable to many test tool programs and mimics the built in one-hot decoder function of the test tool program to ensure that a level of clock gate logic is selected and enabled. To mimic the one hot decoder behavior the built-in functions of the specific test tool are used during test pattern generation.

The architecture, 500 incorporates a multi-level clock gate select logic block programmed in accordance with the built-in tool functions for the specific test tool being used. Multi-level clock gate select logic block 502 receives input that may include a list of flip-flops to be tested, and may also include the specific pins to be tested. Multi-level clock gate select logic block 502 provides for selection between clock input (clk), a functional enable command (en), and a test enable command (te). Multi-level clock gate select logic provides a level 1 test enable command (L1_TE) to multi-level clock gate select logic blocks in the first level, in FIG. 5, multi-level clock gate logic select blocks 504, 506, and 508. The multi-level clock gate logic blocks 504, 506, and 508 then disseminate the test enable inputs to the flip-flops or pins in the first level of the clock tree. This process may be repeated for additional levels of the clock tree as illustrated in FIG. 5. Similarly a level 2 test enable command (L2_TE) may be provided to test a second level, a level 3 test enable command (L3_TE) may be provided to test a third level, and a level 4 test enable command (L4_TE) may be provided to test a fourth level of the DUT. The number of levels may vary with the complexity of the device.

There are many test tools that may be used in this type of testing including: Synopsis-TMAX, Mentor-Fast Scan, and Cadence-ET. For example, the Synopsis-TMAX tool uses additional automated test pattern generation primitives in a selection set to provide information on the flip-flops to be tested. This creates a logical function “sel1” with all of the pins listed in the command “Sel1” is the function keyword. The output of this logic will be 1 if one input is 1 with all other inputs 0. If two or more inputs are 1 the output of this logic will be 0. If all inputs are 0 then the output will also be 0. All other conditions are X. Additional automatic test pattern generation constraints may be added. When the architecture specific logical function described above is set to 1, the test tool is directed to apply the one hot decoder values are applied to the listed pins when the automatic test pattern generation function is activated.

If the Mentor-Fast Scan test tool is used, then additional automatic test pattern generation functions that are user defines are used to create the input flip-flop list. The command for these additional automatic test pattern generation functions may be: add_atpg_functions user_defined_function_name select1. For the select1 function is a high state (logic value 1) if one input is at a high state and the other inputs are at a logic low state (logic value 0). If the output of the function is a logic low state then there are at least two inputs at a logic high state, or, all inputs are at a logic low state.

For Cadence-ET the virtual constraint function may be used to enable the same functionality as described above.

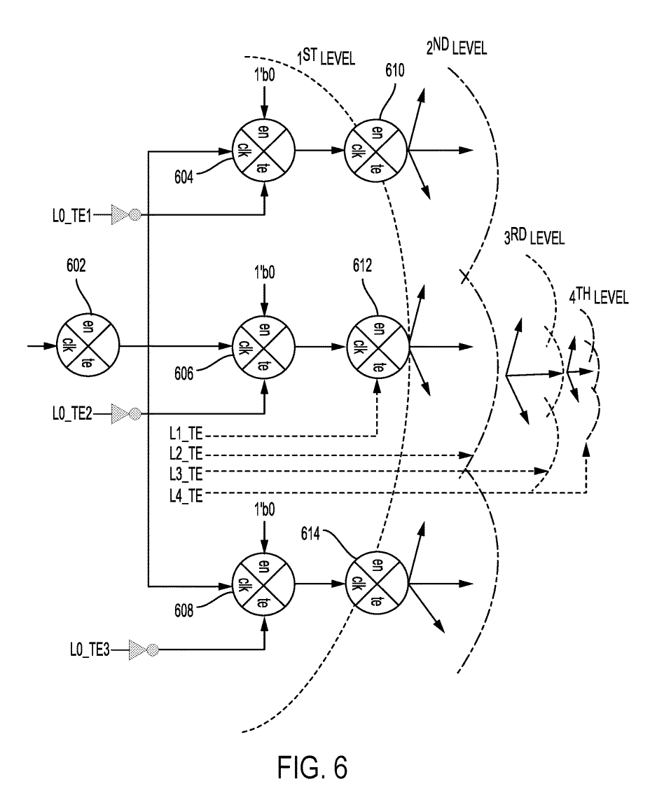

FIG. 6 illustrates an embodiment of an architecture that provides coarse grain control and multi-level clock gate control for use in testing SoCs or other devices. The architecture 600 adds an additional level of clock gate controls at the start of the clock tree. This embodiment provides separate control for each of the level 0 clock gates. Multi-level clock gate select logic block 602 receives input that may include a list of flip-flops to be tested. Multi-level clock gate select logic 602 provides input to the level 0 multi-level clock gate select logic blocks 604, 606, and 608. Multi-level clock gate select logic block 602 provides for selection between clock input (clk), a functional enable command (en), and a test enable command (te). With multi-level clock gate select logic blocks 604, 606, and 608 separate control is provided to each of the level 0 clock gates. This is indicated by the level 0 test enable commands, L0_TE1, which is input to multi-level clock gate select logic 604, L0_TE2, which is input to multi-level clock gate select logic 606, and L0_TE3 which is input to multi-level clock gate select logic 608. Multi-level clock gate select logic blocks 604, 606, and 608 also receive an input to the enable logic of 1′b0. 1′b0 is a Verilog syntax for a constant value that is a one bit number expressed in binary format with a value of 0. This is used to ensure that the function enable feature is not used during testing. This value holds throughout the use of the embodiment shown in FIG. 6. The number of level 0 multi-level clock gate select logic blocks is not limited to the three shown, and the architecture may be adapted to the number needed for the DUT.

Multi-level clock gate select logic block 602 provides input to each of multi-level clock gate select logic blocks 604, 606, and 608. Clock logic block 604 provides input to clock logic block 610. Clock logic block 606 provides input to clock logic block 612. Clock logic block 608 provides input to clock logic block 614.

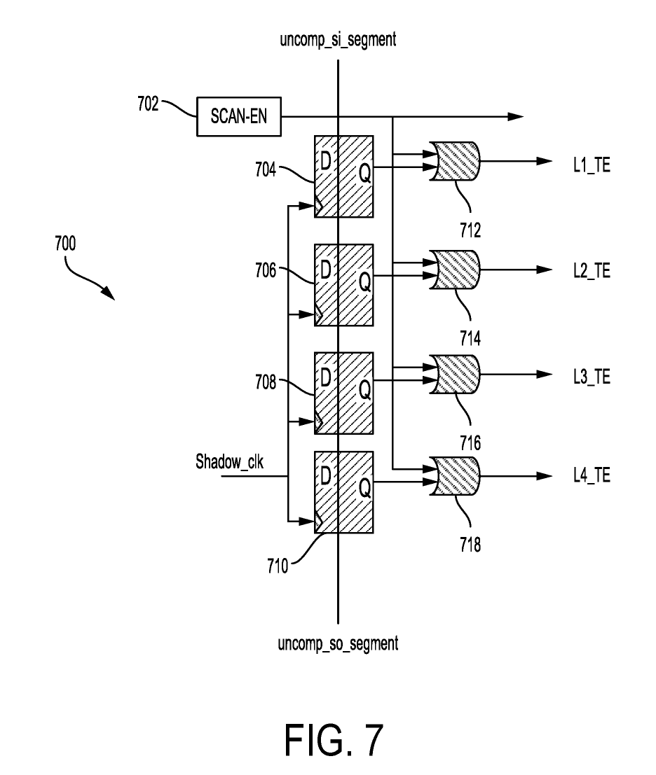

FIG. 7 is a circuit diagram of the circuit used to control the test enable feature according to embodiments described herein. The test enable control circuit 700, includes multiple D flip-flops 704, 706, 708, and 710. These D flip-flops receive the scan enable signal 702, which is generated by the automatic test pattern generation (ATPG) equipment, which is not illustrated in FIG. 7. The D flip-flops 704, 706, 708, and 710 operate to process when an uncompressed segment input select (uncomp_si_segment) is input. The uncomp_si_segment is also input to multiple OR gates 712, 714, 716, and 718. OR gate 712 outputs the L1 test enable signal (L1_TE), OR gate 714 outputs the L2 test enable signal (L2)_TE), OR gate 716 outputs the L3 test enable signal (L3_TE), and OR gate 718 outputs the L4 test enable signal (L4_TE). The D flip-flops 704, 706, 708, and 710 output an uncompressed segment output select signal. The shadow clock is the clock for a shadow flip flop used in field programmable gate array (FPGA) circuits to measure the delay of a signal path. The flip flop used in this case is called the “shadow” flip flop. Thus, the clock driving the “shadow flip flop” is called the “shadow clock.”

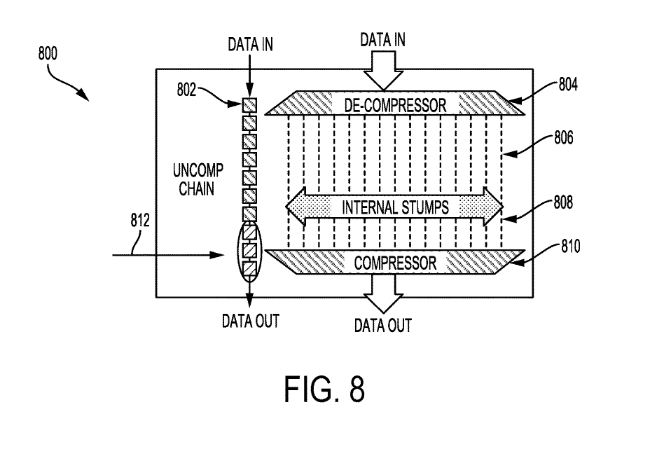

FIG. 8 depicts the system architecture that supports multi-level clock gate test enable control in accordance with embodiments described herein. The architecture 800 includes flip-flop chain 802 that includes additional clock gate control flip-flops 812 added near the data out segment of the uncompressed flip-flop chain 802. Data in enters the decompressor 804 wherein multiple channels may be initialized. The additional clock gate control flip-flops 812 correspond to the circuit diagram of FIG. 7. The additional flip-flops 812 enable multi-level clock gate control of the test enable circuit. The uncompressed chain 806 is input to compressor 810. Internal stumps 808 are also provided in the uncompressed chain 806. Since the constrained flip-flops 812 are part of the uncompressed chain 806, aliasing/controllability, and pattern inflation issues do not arise. A further embodiment provides for a similar structure for use with the level 0 test enable controls (L0_TE).

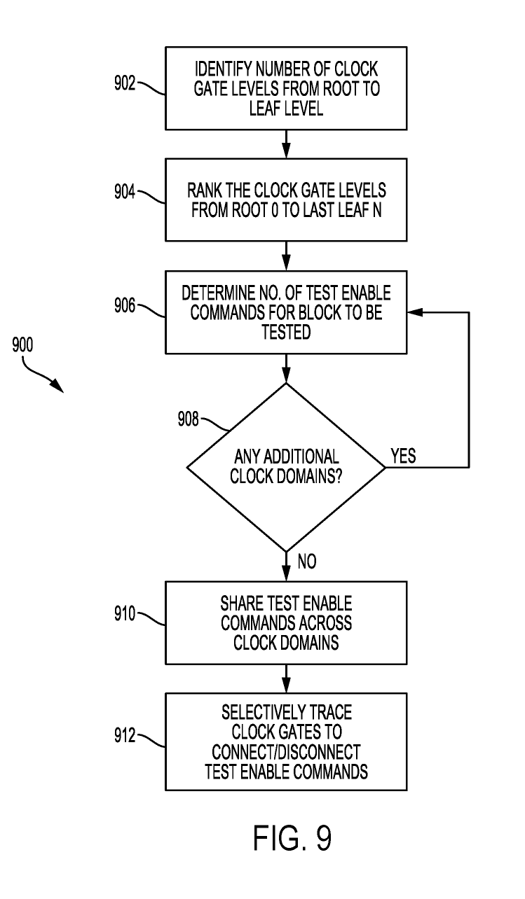

FIG. 9 is a flowchart of a method that provides multi-level clock gate control to address scan mode power droop and voltage bump requirements, in accordance with the embodiments described above. The method 900 begins when the number of clock gate levels in the design are identified in block 902. The clock gate levels are identified from the root level to the leaf level. Once the clock gate levels have been identified in block 902, they are ranked from the root level which is designated 0 to the last leaf level, which is designated “N,” in block 904. More complex designs may have multiple levels of leaves, however, the method described may be used with multiple level designs. In block 906 the number of test enable commands needed for the block to be tested may be determined. Next, in decision block 908, a query determines if any additional clock domains should be tested. If the answer is Yes, then the method moves back to block 904 and the number of test enable commands for the new clock domain is determined. If the answer is No, then the method proceeds to block 910. In block 910 the test enable commands may be shared across the clock domains. After sharing the test enable commands across the clock domains, the method proceeds to block 912, where the method provides for selectively tracing the clock gates to connect and disconnect as needed the test enable commands

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the present disclosure.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more exemplary embodiments, the functions described may be implemented in hardware, software, firmware, or any combination thereof. If implemented in software, the functions may be stored on or transmitter over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM EEPROM, CD-ROM or other optical disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the present disclosure. Various modifications to these exemplary embodiments will be readily apparent to those skilled in the art, and the generic principles defined herein may be applied to other embodiments without departing from the spirit or scope of the present disclosure. Thus, the present disclosure is not intended to be limited to the exemplary embodiments shown herein but is to be accorded the widest scope consistent with the principles and novel features disclosed herein.

What is claimed is:

1. A method of multi-level clock gate control for testing electronic devices, comprising:
identifying a number of clock gate levels from root level to last leaf level;
ranking the clock gate levels from the root level to the last leaf level;
determining a number of test enable commands for at least one test block of an electronic device;
selectively connecting and disconnecting the test enable commands based on the ranked clock gate levels; and
testing the at least one test block of the electronic device.

2. The method of claim 1, wherein the number of test enable commands is based on a maximum number of flip-flops in a clock domain.

3. The method of claim 1, wherein the test enable commands are shared across multiple clock domains.

4. The method of claim 1, further comprising: tracing clock gates for connection and disconnection of the test enable commands based on the ranking of clock gate levels.

5. The method of claim 4, wherein a test enable command is set to a logic high to disconnect the test enable command for at least one test block.

6. The method of claim 4, wherein a test enable command is set to a logic low to connect the test enable command for at least one test block.

7. An apparatus for multi-level clock gate control for testing electronic devices, comprising:
a chain of at least two uncompressed flip-flops in an uncompressed chain of flip-flops;
at least one flip-flop in communication with an OR gate, in communication with the chain of at least two uncompressed flip-flops in an uncompressed chain of flip-flops;
a decompressor in communication with the chain of at least two uncompressed flip-flops in an uncompressed chain of flip-flops and the at least one flip-flop in communication with an OR gate; and
a compressor in communication with the decompressor and the chain of at least two uncompressed flip-flops and the at least one flip-flop in communication with an OR gate.

8. The apparatus of claim 8, wherein the at least one flip-flop in communication with an OR gate controls one level of testing of the uncompressed chain of flip-flops.

9. The apparatus of claim 8, wherein a number of flip-flops in communication with an OR gate is based on a number of ranked levels to be tested.

10. The apparatus of claim 8, wherein the at least one flip-flop in communication with an OR gate is connected at an end of the uncompressed chain of flip-flops.

11. An apparatus for multi-level clock gate control for testing electronic devices, comprising:
means for identifying a number of clock gate levels from root level to last leaf level;
means for ranking the clock gate levels from the root level to the last leaf level;
means for determining a number of test enable commands for at least one test block of an electronic device;
means for selectively connecting and disconnecting the test enable commands based on the ranked clock gate levels; and
means for testing the at least one electronic device.

12. The apparatus of claim 11, wherein the means for determining a number of test enable commands is based on a maximum number of flip-flops in a clock domain.

13. The apparatus of claim 11, further comprising means for sharing test enable commands across multiple clock domains.

14. The apparatus of claim 11, further comprising means for tracing clock gates for connection and disconnection of the the test enable command for at least one test block.

15. The apparatus of claim 14, further comprising means for setting a logic high in a test enable command to disconnect the test enable command for at least one test block.

16. The apparatus of claim 14, further comprising means for setting a logic low in a test enable command to connect the test enable command for at least one test block.

17. A non-transitory computer-readable medium containing instructions, which when performed by a processor, cause the processor to perform the following steps:
identify a number of clock gate levels from root level to last leaf level;
rank the clock gate levels from the root level to the last leaf level;
determine a number of test enable commands for at least one test block of an electronic device;
selectively connect and disconnect the test enable commands based on the ranked clock gate levels; and
test the at least one test block of the electronic device.

18. The non-transitory computer-readable medium of claim 17, wherein the number of test enable commands performed by the processor is based on a maximum number of flip-flops in a clock domain.

19. The non-transitory computer-readable instructions of claim 17, wherein the processor shares the test enable commands across multiple clock domains.

20. The non-transitory computer-readable instructions of claim 17, further comprising instructions for tracing clock gates for connection and disconnection of the test enable commands based on the ranking of clock gate levels.

21. The non-transitory computer-readable medium of claim 20, wherein the instructions set a logic high to disconnect the test enable command for at least one test block.

22. The non-transitory computer-readable medium of claim 20, wherein the instructions set a logic low to connect the test enable command for at least one test block.
